(19) United States
(12) Patent Application Publication
(10) Pub. No.: US 2014/0175367 A1
(43) Pub. Date: Jun. 26, 2014

(54) Materials for Thin Resisive Switching Layers of Re-RAM Cells

(71) Applicants: INTERMOLECULAR INC., San Jose, CA (US); KABUSHIKI KAISHA TOSHIBA, Tokyo (JP); SANDISK 3D LLC, Milpitas, CA (US)

(72) Inventors: Mihir Tendulkar, Mountain View, CA (US); Vidyut Gopal, Sunnyvale, CA (US); Imran Hashim, Saratoga, CA (US); Tim Minvielle, San Jose, CA (US); Yun Wang, San Jose, CA (US); Takeshi Yamaguchi, Kanagawa (JP)

(73) Assignees: INTERMOLECULAR INC., San Jose, CA (US); SANDISK 3D LLC, Milpitas, CA (US); KABUSHIKI KAISHA TOSHIBA, Tokyo (JP)

(21) Appl. No.: 13/722,569

(22) Filed: Dec. 20, 2012

(51) Int. Cl. H01L 45/00

(52) U.S. Cl. CPC H01L 45/147; H01L 45/1616
USPC 257/4; 438/104

(57) ABSTRACT

Provided are resistive random access memory (ReRAM) cells that include thin resistive switching layers. In some embodiments, the resistive switching layers have a thickness of less than about 50 Angstroms and even less than about 30 Angstroms. The resistive switching characteristics of such thin layers are maintained by controlling their compositions and using particular fabrication techniques. Specifically, low oxygen vacancy metal oxides, such as tantalum oxide, may be used. The concentration of oxygen vacancies may be less than 5 atomic percent. In some embodiments, the resistive switching layers also include nitrogen and. For example, compositions of some specific resistive switching layers may be represented by Ta₂O_{5-X}N_{Y}, where Y<(X−0.01). The resistive switching layers may be formed using Atomic Layer Deposition (ALD).

### TECHNICAL FIELD

The present invention relates generally to non-volatile memory and more specifically to thin resistive switching layers for resistive random access memory (ReRAM) cells including materials, structures, and methods of fabricating these resistive switching layers.

### BACKGROUND

Nonvolatile memory is computer memory capable of retaining the stored information even when unpowered. Non-volatile memory is typically used for the task of secondary storage or long-term persistent storage and may be used in addition to volatile memory, which losses the stored information when unpowered. Nonvolatile memory can be permanently integrated into computer systems (e.g., solid state hard drives) or can take the form of removable and easily transportable memory cards (e.g., USB flash drives). Nonvolatile memory is becoming more popular because of its small size/high density, low power consumption, fast read and write rates, retention, and other characteristics.

Flash memory is a common type of nonvolatile memory because of its high density and low fabrication costs. Flash memory is a transistor-based memory device that uses multiple gates per transistor and quantum tunneling for storing the information on its memory device. Flash memory uses a block-access architecture that can result in long access, erase, and write times. Flash memory also suffers from low endurance, high power consumption, and scaling limitations.

The constantly increasing speed of electronic devices and storage demand drive new requirements for nonvolatile memory. For example, nonvolatile memory is expected to replace hard drives in some computer systems. However, transistor-based flash memory is often inadequate to meet the requirements of various applications. New types of memory, such as resistive random access memory (ReRAM), are being developed to meet these demands and requirements.

### SUMMARY

Provided are resistive random access memory (ReRAM) cells that include thin resistive switching layers. In some embodiments, the resistive switching layers have a thickness of less than about 50 Angstroms and even less than about 30 Angstroms. The resistive switching characteristics of such thin layers are maintained by controlling their compositions and using particular fabrication techniques. Specifically, low oxygen vacancy metal oxides, such as tantalum oxide, may be used. The concentration of oxygen vacancies may be less than 5 atomic percent. In some embodiments, the resistive switching layers also include nitrogen. For example, compositions of some resistive switching layers may be represented by Ta₂O_{5-X}N_{Y}, where Y<(X−0.01). The resistive switching layers may be formed using Atomic Layer Deposition (ALD).

In some embodiments, a resistive random access memory cell includes a first layer operable as a first electrode, a second layer includes a resistive switching material, and a third layer operable as a second electrode. The resistive switching material may have a concentration of oxygen vacancies that is less than about 5 atomic percent. For example, the concentration may be between about 0.1 and 4 atomic percent or, more specifically between about 0.5 and 3 atomic percent. The second layer may be less than about 50 Angstroms thick. The second layer is positioned between the first layer and the second layer.

In some embodiments, the resistive switching material further includes nitrogen. The resistive switching material may include tantalum oxide. In some embodiments, the resistive switching material includes tantalum and nitrogen. In some embodiments, the resistive switching material is represented by a formula Ta₂O_{5-X}N_{Y} such that Y<(X−0.01). The second layer has a thickness of less than 30 Angstroms. In some embodiments, the concentration of oxygen vacancies in the resistive switching material is less than 3 atomic percent.

In some embodiments, the third layer includes titanium nitride. The thickness of the third layer may be less than 1,000 Angstroms. In some embodiments, the first layer includes n-doped polysilicon.

Provided also is a method of forming a resistive random access memory cell. The method may involve forming a first layer operable as a first electrode, forming a second layer over the first layer, and forming a third layer over the second layer. The second layer includes a resistive switching material containing a metal oxide having a concentration of oxygen vacancies of less than 5 atomic percent. The second layer has a thickness of less than 50 Angstroms. The third layer operable as a second electrode. The second layer is formed using Atomic Layer Deposition (ALD). The concentration of oxygen vacancies is achieved by controlling saturation of an oxygen containing reagent during ALD.

In some embodiments, the second layer includes tantalum. A precursor used for depositing the second layer is one of pentakis (dimethylamino) tantalum, tris(diethylamido) (tert-butylimido) tantalum, tris(diethylamido) (ethylimido) tantalum, or tris(ethylmethylamido) (tert-butylimido) tantalum. In some embodiments, a nitrogen containing reagent is used during the ALD forming.

In some embodiments, the first layer is formed using Chemical Vapor Deposition (CVD). The first layer may be deposited using n-doped polysilicon. The third layer may be formed using Physical Vapor Deposition (PVD). The third layer may include titanium nitride. In some embodiments, the first layer is formed using CVD, while the second layer is formed using Atomic Layer Deposition (ALD). The first layer includes n-doped polysilicon. The resistive switching material of the second layer is represented by a formula Ta₂O_{5-X}N_{Y} such that Y<(X−0.01).

Provided also is a resistive random access memory cell including a first layer operable as a first electrode, a second layer including a resistive switching material, and a third layer operable as a second electrode. The first layer may include n-doped polysilicon. The resistive switching material of the second layer may be represented by a formula Ta₂O_{5-X}N_{Y} such that Y<(X−0.01). The resistive switching material may have a concentration of oxygen vacancies of less than 5 atomic percent. The second layer having a thickness of less than 50 Angstroms. The third layer may include a titanium nitride and may have a thickness of less than 1,000 Angstroms. The second layer is positioned between the first layer and the second layer.

### BRIEF DESCRIPTION OF THE DRAWINGS

To facilitate understanding, the same reference numerals have been used, where possible, to designate common components presented in the figures. The drawings are not to scale and the relative dimensions of various elements in the drawings are depicted schematically and not necessarily to scale. Various embodiments can readily be understood by considering the following detailed description in conjunction with the accompanying drawings, in which:

FIGS. 1A and 1B illustrate schematic representations of a nonvolatile memory element in its high resistive state (HRS) and low resistive state (LRS), in accordance with some embodiments.

FIG. 2 illustrates a plot of a current passing through a nonvolatile memory element as a function of a voltage applied to the nonvolatile memory element, in accordance with some embodiments.

FIG. 3A illustrates a schematic representation of a ReRAM cell with a thin resistive switching layer, in accordance with some embodiments.

FIG. 3B illustrates a plot of a median set voltage as a function of a thickness and oxygen concentration of tantalum oxide resistive switching layers.

FIG. 3C illustrates a plot of a median set transient current as a function of a thickness and oxygen concentration of tantalum oxide resistive switching layers.

FIG. 3D illustrates a plot of a forming voltage as a function of a thickness and oxygen concentration of tantalum oxide resistive switching layers.

FIG. 4 illustrates a process flowchart corresponding to a method for forming a ReRAM cell having a thin resistive switching layer, in accordance with some embodiments.

FIG. 5 illustrates a schematic representation of a processing apparatus suitable for deposition resistive switching layers using Atomic Layer Deposition (ALD), in accordance with some embodiments.

FIGS. 6A and 6B illustrate schematic views of memory arrays including multiple ReRAM cells, in accordance with some embodiments.

### DETAILED DESCRIPTION

A detailed description of various embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

### Introduction

A ReRAM cell exhibiting resistive switching characteristics generally includes multiple layers formed into a stack. This stack is often labeled as a Metal-Insulator-Metal (MIM) stack. The stack includes two conductive layers operating as electrodes, which may include metals and other conductive materials, such as doped silicon. These conductive layers are identified as “M” in the above naming convention. The stack also includes an insulator layer disposed between the electrodes. The insulator layer is indentified as “I” above. The insulator layer exhibits resistive switching properties characterized by different resistive states, which may be used to store one or more bits of information. For example, one resistive state may be used to represent a logical “zero,” while another resistive state may be used to represent a logical “one.” The insulator is often referred to as a resistive switching layer. The difference in the resistive states may be attributed to changes in the insulator layer, changes at one or both interfaces between the insulator layer and metal layers, or both types of changes.

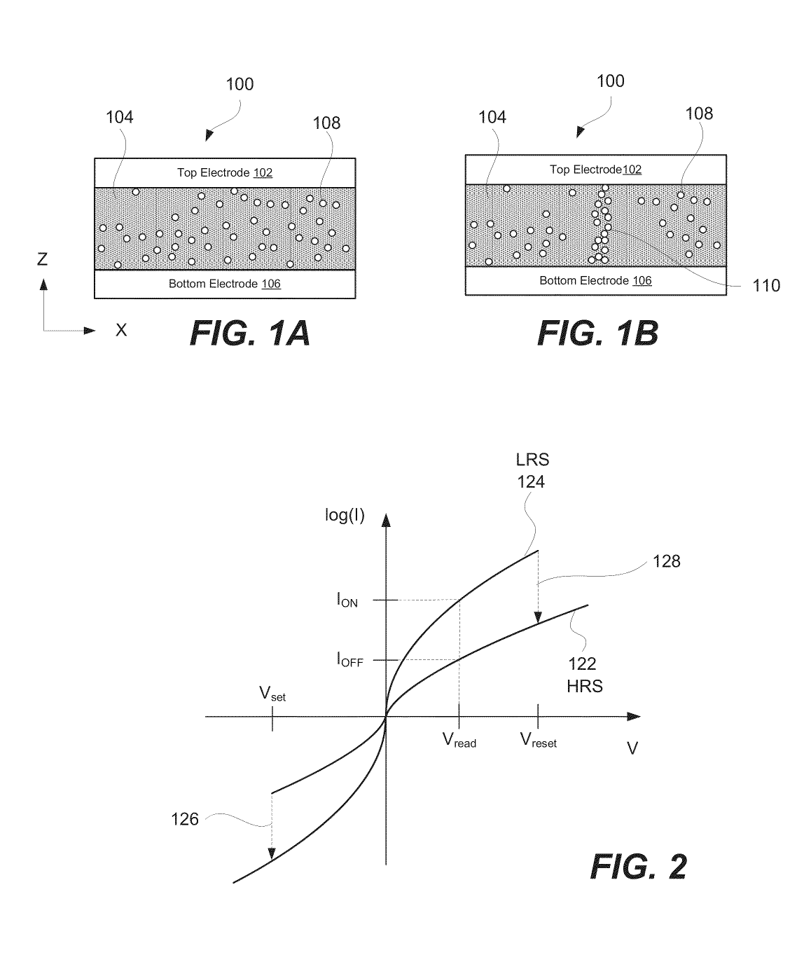

Without being restricted to any particular theory, it is believed that the resistive switching properties of the insulator layer depend on defect concentrations inside this layer. For example, oxygen vacancies in metal oxides are believed to be responsible for different restive states depending on their distribution within the resistive switching layer. Additional description of defects is presented below with reference to FIGS. 1A and 1B. The thickness of the resistive switching layer plays an important role in determining its switching characteristics.

From an integration perspective, thinner ReRAM stacks are more desirable, as they allow manufacturing of smaller integrated circuits. Furthermore, thin ReRAM stacks may be used in 3D memory architectures. While electrodes can be easily scaled down and even integrated into other components, such as signal lines, scalability of resistive switching layers present significant challenges. Conventional ReRAM cell designs use resistive switching layers that are at least 100 Angstroms thick. Previous attempts to scale down these layers have run into various performance and fabrication issues. For example, thinning conventional metal oxides used for ReRAM applications led to higher set and forming voltages, which is not desirable from the performance standpoint.

Provided are ReRAM cells that include thin resistive switching layers having defined compositions. In some embodiments, the resistive switching layers have a thickness of less than about 50 Angstroms and even less than about 30 Angstroms. The resistive switching characteristics are maintained within the desirable ranges by controlling their compositions. Specifically, metal oxides, such as tantalum oxide, that have less than 5 atomic percent of oxygen vacancies may be used or even less than 3 atomic percent of oxygen vacancies. It should be noted that an oxide of the same metal may vary in terms of oxygen concentration.

Properties of the resistive switching materials are specifically tuned to compensate for the tradeoffs associated with a thinner layer. One aspect of this tuning is based on reducing concentrations of oxygen vacancies. Lower concentrations are believed to restrict mobility of the oxygen vacancies within the resistive switching layer and, as a result, change its resistive switching characteristics. Various examples presented below focus on tantalum oxide layers. However, one having ordinary skills in the art would understand that the same approach could be used for other oxides that may be used in ReRAM cell, such as nickel oxide, niobium oxide, titanium oxide, hafnium oxide, aluminum oxide, zirconium oxide, yttrium oxide, scandium oxide, magnesium oxide, chromium dioxide, and vanadium oxide. It should be noted that oxides used in ReRAM cells typically deviate from their stoichiometric form and generally more metal is present in these ReRAM oxides than in the stoichiometric oxides. Furthermore, controlling stoichiometric deviations may be applied to nitrides, such as boron nitride and aluminum nitride, in a manner similar to oxides. In some embodiments, various combinations of nitrides and oxides may be used in the same resistive switching layer. Some examples of a resistive switching material is represented by a formula Ta₂O_{5-X}N_{Y} such that Y<(X−0.01).

The thin resistive switching layers described herein have resistive switching properties comparable to conventional thicker layers. For example, a voltage used to switch a resistive switching layer from its low resistance state to its high resistance state, which is also referred to a set voltage as further described below with reference to FIGS. 1A-1B and 2 may need to be less than 2 V for both types of these layers. It has been known that such a low set voltage may be achieved with some oxygen deficient (i.e., metal rich) metal oxides that are at least 250 Angstroms thick. However, it has been unexpectedly found that the same performance can be achieved with oxygen rich oxides that are less than 50 Angstroms thick. For purposes of this document, the terms “oxygen rich”, “stoichiometric” or “near stoichiometric” are used for oxides that have less than about 5 atomic percent of oxygen vacancies. It should be noted that conventional metal oxides that are used for thicker layers generally have a concentration of oxygen vacancies of at least 10 atomic % and are referred to as “oxygen deficient” or “metal rich” oxides. Another unexpected result relates to transient currents that appear during set operations, which are also referred to as set transients. These are current overshoots passing through a resistive switching layer when it is switched from its low to high resistance state (i.e., when a set voltage is applied to the cell). In some embodiments, it may be desirable to have set transients below 50 micro Ampere. Similar to the set voltage described above, metal rich oxides can meet this transient current requirement when formed into thick layers (e.g., more than 100 Angstroms). At the same time, the proposed oxygen rich oxides have the same performance when formed into substantially thinner layers, such as less than 50 Angstroms.

The resistive switching layers described herein may be used with various types of electrodes, such as titanium nitride and n-doped poly-silicon electrodes. The electrodes are typically formed using chemical vapor deposition (CVD) and/or physical vapor deposition (PVD) techniques. While these deposition techniques are also suitable for conventional thicker layers, the described thinner layers are typically deposited using Atomic Layer Deposition (ALD).

Examples of Re-RAM Cells and their Switching Mechanisms

A brief description of ReRAM cells and their switching mechanisms are provided for better understanding of various features and structures associated with methods of forming ReRAM cells further described below. ReRAM is a non-volatile memory type that includes dielectric material exhibiting resistive switching characteristics. A dielectric, which is normally insulating, can be made to conduct through one or more filaments or conduction paths formed after application of a sufficiently high voltage. The conduction path formation can arise from different mechanisms, including defects, metal migration, and other mechanisms further described below. Once the one or more filaments or conduction paths are formed in the dielectric component of a memory device, these filaments or conduction paths may be reset (or broken resulting in a high resistance) or set (or re-formed resulting in a lower resistance) by applying certain voltages.

A basic building unit of a memory device is a stack having a capacitor like structure. A ReRAM cell includes two electrodes and a dielectric positioned in between these two electrodes. FIG. 1A illustrates a schematic representation of ReRAM cell 100 including top electrode 102, bottom electrode 106, and resistance switching layer 104 provided in between top electrode 102 and bottom electrode 106. It should be noted that the “top” and “bottom” references for electrodes 102 and 106 are used solely for differentiation and not to imply any particular spatial orientation of these electrodes. Often other references, such as “first formed” and “second formed” electrodes or simply “first” and “second”, are used identify the two electrodes. ReRAM cell 100 may also include other components, such as an embedded resistor, diode, and other components. ReRAM cell 100 is sometimes referred to as a memory element or a memory unit.

As stated above, resistance switching layer 104, which is made of a dielectric material, can be made to conduct through one or more filaments or conduction paths formed by applying a certain voltage. To provide this resistive switching functionality, resistance switching layer 104 includes a certain concentration of electrically active defects 108, which are sometimes referred to as traps. For example, some charge carriers may be absent from the structure (i.e., vacancies) and/or additional charge carriers may be present (i.e., interstitials) representing defects 108. In some embodiments, defects may be formed by impurities (i.e., substitutions). These defects may be utilized for ReRAM cells operating according to a valence change mechanism, which may occur in specific transition metal oxides and is triggered by a migration of anions, such as oxygen anions. Migrations of oxygen anions may be represented by the motion of the corresponding vacancies, i.e., oxygen vacancies. A subsequent change of the stoichiometry in the transition metal oxides leads to a redox reaction expressed by a valence change of the cation sublattice and a change in the electronic conductivity. In this example, the polarity of the pulse used to perform this change determines the direction of the change, i.e., reduction or oxidation. Other resistive switching mechanisms include bipolar electrochemical metallization mechanism and thermochemical mechanism, which leads to a change of the stoichiometry due to a current-induced increase of the temperature.

Without being restricted to any particular theory, it is believed that defects 108 can be reoriented within resistance switching layer 104 to form filaments or conduction paths as, for example, schematically shown in FIG. 1B as element 110. This reorientation of defects 108 occurs when a voltage for this type of resistance switching layer 104 is applied to electrodes 102 and 106. Sometimes, reorientation of defects 108 is referred to as filling the traps by applying a set voltages (and forming one or more filaments or conduction paths) and emptying the traps by applying a reset voltage (and breaking the previously formed filaments or conduction paths).

Defects 108 can be introduced into resistance switching layer 104 during or after its fabrication. For example, a certain concentration of oxygen deficiencies can be introduced into metal oxides during their deposition or during subsequent annealing. Physical vapor deposition (PVD) and atomic layer deposition (ALD) techniques may be specifically tuned to include particular defects 108 and their distribution within resistance switching layer 104.

Operation of ReRAM cell 100 will now be briefly described with reference to FIG. 2 illustrating a logarithmic plot of a current passing through a ReRAM cell as a function of a voltage applied to the electrode of ReRAM cell, in accordance with some embodiments. ReRAM cell 100 may be either in a low resistive state (LRS) defined by line 124 or high resistive state (HRS) defined by line 122. Each of these states is used to represent a different logic state, e.g., HRS representing logic one and LRS representing logic zero or vice versa. Therefore, each ReRAM cell that has two resistance states may be used to store one bit of data. It should be noted that some ReRAM cells may have three and even more resistance states allowing multi-bit storage in the same cell.

HRS and LRS are defined by presence or absence of one or more filaments or conduction paths in resistance switching layer 104 and forming connections between these filaments or conduction paths and two electrodes 102 and 106. For example, a ReRAM cell may be initially fabricated in LRS and then switched to HRS. A ReRAM cell may be switched back and forth between LRS and HRS many times, defined by set and reset cycles. Furthermore, a ReRAM cell may maintain its LRS or HRS for a substantial period of time and withstand a number of read cycles.

The overall operation of ReRAM cell 100 may be divided into a read operation, set operation (i.e., turning the cell “ON”), and reset operation (i.e., turning the cell “OFF”). During the read operation, the state of ReRAM cell 100 or, more specifically, the resistance of resistance switching layer 104 can be sensed by applying a sensing voltage to electrodes 102 and 106. The sensing voltage is sometimes referred to as a “READ” voltage and indicated as V_{READ} in FIG. 2. If ReRAM cell 100 is in HRS represented by line 122, the external read and write circuitry connected to electrodes 102 and 106 will sense the resulting “OFF” current (I_{OFF}) that flows through ReRAM cell 100. As stated above, this read operation may be performed multiple times without switching ReRAM cell 100 between HRS and LRS. In the above example, the ReRAM cell 100 should continue to output the “OFF” current (I_{OFF}) when the read voltage (V_{READ}) is applied to the electrodes.

Continuing with the above example, when it is desired to switch ReRAM cell 100 into a different logic state, ReRAM cell 100 is switched from its HRS to LRS. This operation is referred to as a set operation. This may be accomplished by using the same read and write circuitry to apply a set voltage (V_{SET}) to electrodes 102 and 106. Applying the set voltage (V_{SET}) forms one or more filaments or conduction paths in resistance switching layer 104 and switches ReRAM cell 100 from its HRS to LRS as indicated by dashed line 126. It should be noted that formation or breaking of filaments or conduction paths in resistance switching layer 104 may also involve forming or breaking electronic connections between these filaments and one (e.g., reactive electrode) or both electrodes. The overarching concern is passage of the current between the two electrodes.

In LRS, the resistance characteristics of ReRAM cell 100 are represented by line 124. In this LRS, when the read voltage (V_{READ}) is applied to electrodes 102 and 106, the external read and write circuitry will sense the resulting “ON” current (I_{ON}) that flows through ReRAM cell 100. Again, this read operation may be performed multiple times without switching ReRAM cell 100 between LRS and HRS.

It may be desirable to switch ReRAM cell 100 into a different logic state again by switching ReRAM cell 100 from its LRS to HRS. This operation is referred to as a reset operation and should be distinguished from set operation during which ReRAM cell 100 is switched from its HRS to LRS. During the reset operation, a reset voltage (V_{RESET}) is applied to ReRAM cell 100 to break the previously formed filaments or conduction paths in resistance switching layer 104 and switches ReRAM cell 100 from its LRS to HRS as indicated by dashed line 128. Reading of ReRAM cell 100 in its HRS is described above. Overall, ReRAM cell 100 may be switched back and forth between its LRS and HRS many times. Read operations may be performed in each of these states (between the switches) one or more times or not performed at all. It should be noted that application of set and reset voltages to change resistance states of the ReRAM cell involves complex mechanisms that are believed to involve localized resistive heating as well as mobility of defects impacted by both temperature and applied potential.

ReRAM cell 100 may be configured to have either unipolar switching or bipolar switching. The unipolar switching does not depend on the polarity of the set voltage (V_{SET}) and reset voltage (V_{RESET}) applied to the electrodes 102 and 106 and, as a result, to resistance switching layer 104. In the bipolar switching the set voltage (V_{SET}) and reset voltage (V_{RESET}) applied to resistance switching layer 104 need to have different polarities.

In some embodiments, the set voltage (V_{SET}) is between about 100 mV and 10V or, more specifically, between about 500 mV and 5V. The length of set voltage pulses (t_{SET}) may be less than about 100 milliseconds or, more specifically, less than about 5 milliseconds and even less than about 100 nanoseconds. The read voltage (V_{READ}) may be between about 0.1 and 0.5 of the write voltage (V_{SET}). In some embodiments, the current during reading and writing operations may be less than about 5 μA or, more specifically, is less than about 1 μA. The length of read voltage pulse (t_{READ}) may be comparable to the length of the corresponding set voltage pulse (t_{SET}) or may be shorter than the write voltage pulse (t_{SET}).

A ratio of currents generated during set and reset operations may be at least about 5 or, more specifically, at least about 10 to make the state of ReRAM cell easier to determine. ReRAM cells should be able to cycle between LRS and HRS between at least about 10̂3 times or, more specifically, at least about 10̂7 times without failure. A data retention time (t_{RET}) should be at least about 5 years or, more specifically, at least about 10 years at a thermal stress up to 85° C. and small electrical stress, such as a constant application of the read voltage (V_{READ}).

In some embodiments, the same ReRAM cell may include two or more resistance switching layers interconnected in series. Adjacent resistance switching layers may directly interface each other or be separated by an intermediate layer.

In some embodiments, a ReRAM cell is subjected to a forming operation, during which the initially insulating properties of the resistance switching layer are altered and the ReRAM cell is configured into the initial LRS or HRS. The forming operation may include a very short high discharge current peak, which is used to set the LRS level of the resistance switching layer for subsequent switching as outlined above. In this case, a resistance switching layer with very low levels (e.g., 100-30 kOhm) of resistance in the LRS may be limited in terms of scaling down. This difficulty may be resolved by positioning such resistance switching layers in series with other components providing additional resistance to the overall ReRAM cell.

ReRAM Cell Components and their Characteristics

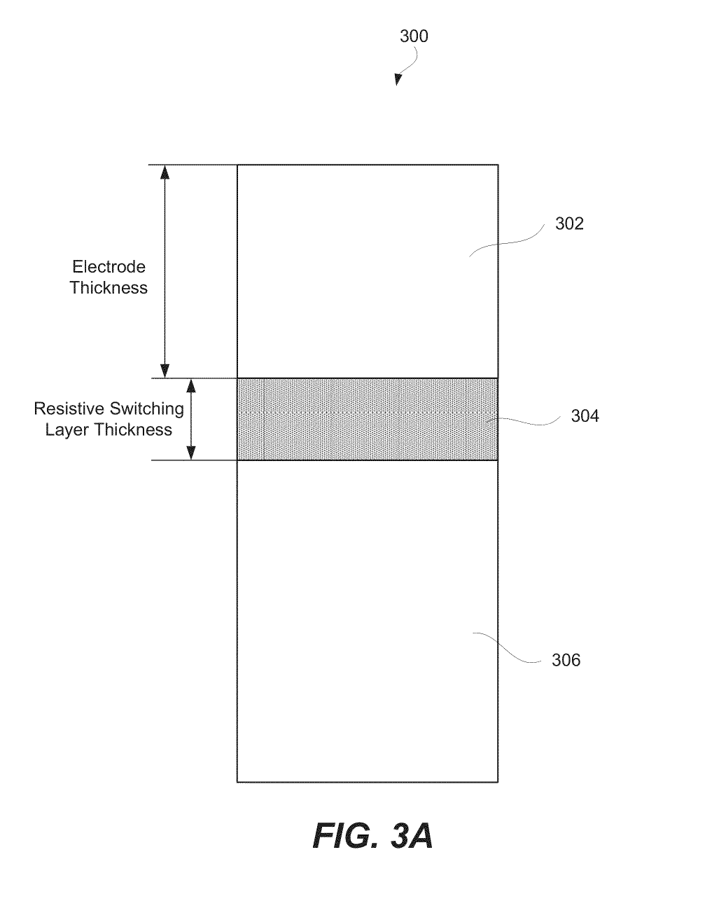

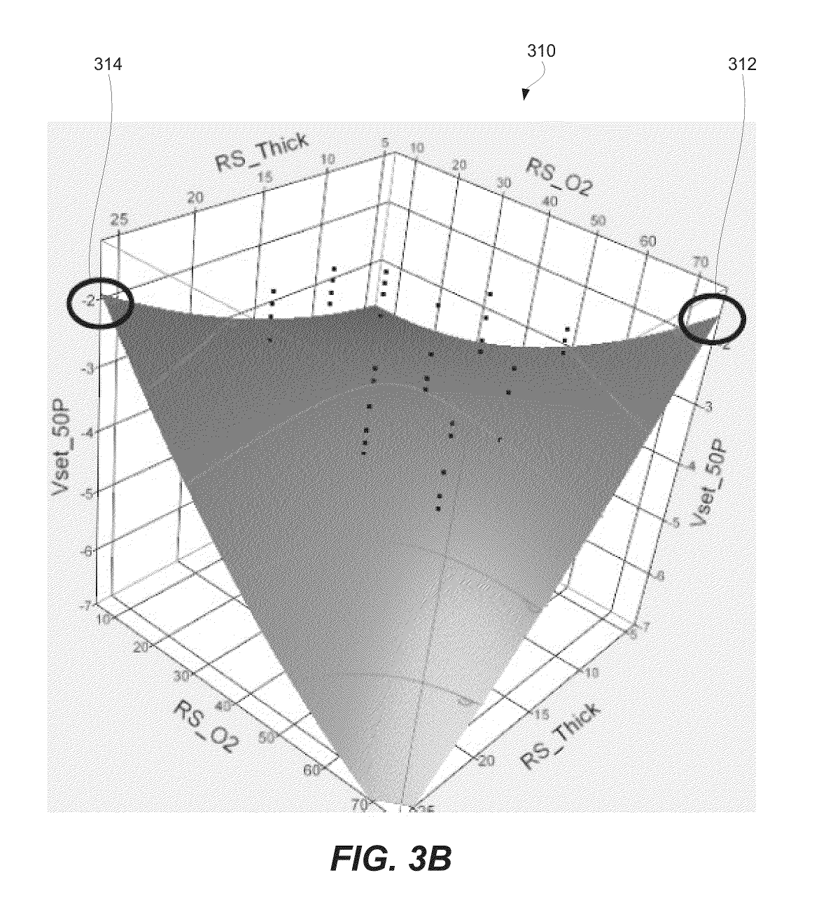

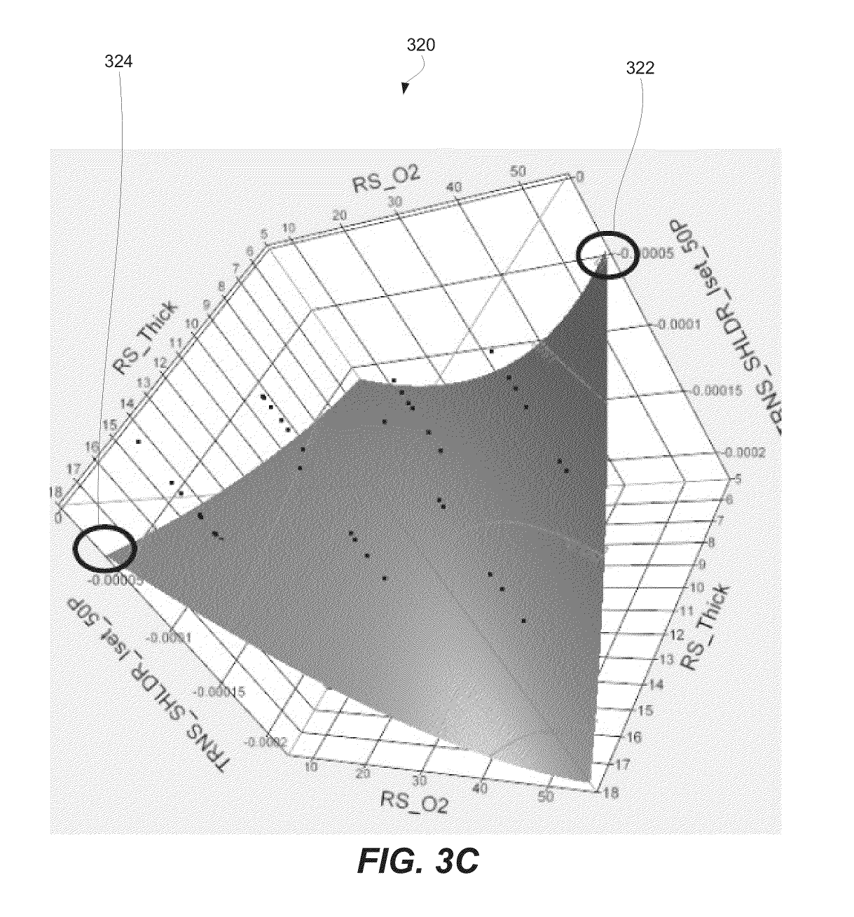

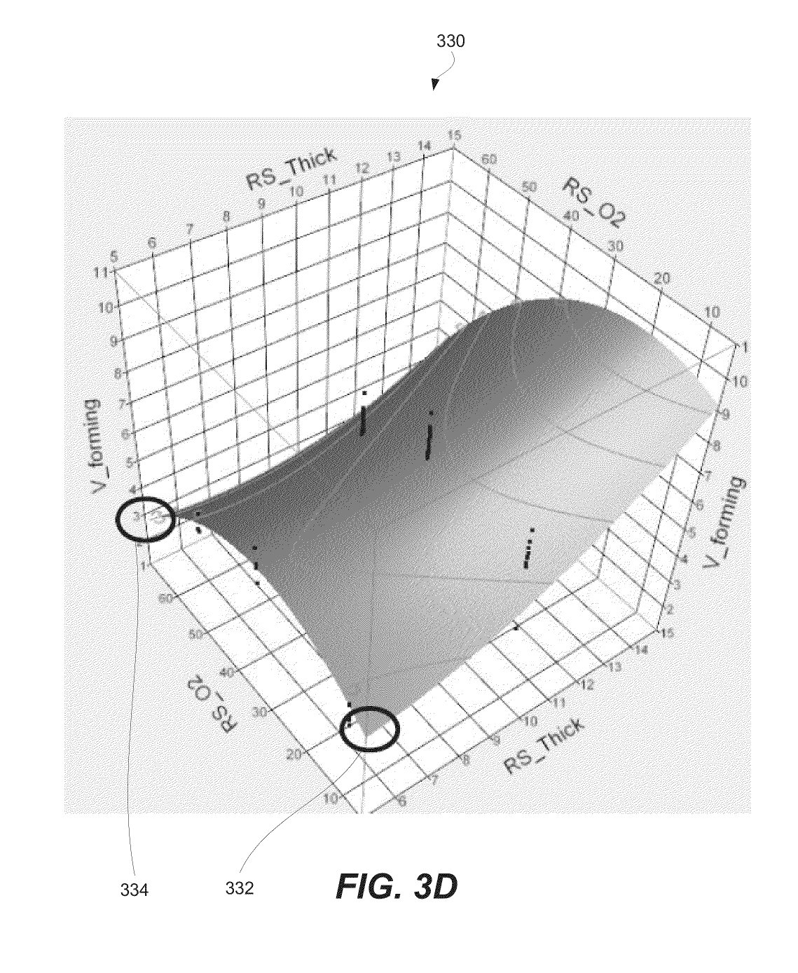

FIG. 3A illustrates a schematic representation of ReRAM cell 300, in accordance with some embodiments. ReRAM cell 300 includes a first electrode 302, a resistive switching layer 304, and a second electrode 306. In some embodiments, ReRAM cell 300 may include other elements, such as a diode, an embedded resistor, a coupling layer, a diffusion barrier layer, and/or one or more additional resistive switching layers. Furthermore, ReRAM cell 300 may include fewer layers. For example, one or both electrodes may be integrated into other components, such as signal lines or one of the components listed above.

First electrode 302 and second electrode 306 may be made from the same or different materials. Some examples of suitable electrode materials include n-doped polysilicon, titanium nitride, ruthenium, iridium, platinum, tantalum nitride, tantalum silicon nitride, and titanium silicon nitride. In some embodiments, one electrode may be formed from titanium nitride, while another electrode may be formed from n-doped polysilicon. First electrode 302 and/or second electrode 306 may have a thickness of less than about 1,000 Angstroms, such as less than about 500 Angstroms and even less than about 100 Angstroms. Thinner electrodes may be formed using ALD techniques. In some embodiments, at least one of the two electrodes is formed in the same processing chamber that is used to form a resistive switching layer. Specifically, these two components may be formed in situ, that is without breaking the vacuum in the processing chamber and exposing the electrode to an oxidizing environment.

Resistive switching layer 304 may include metal oxides and/or other suitable materials that have resistive switching characteristics. Some examples of metal oxides include tantalum oxide, nickel oxide, niobium oxide, titanium oxide, hafnium oxide, aluminum oxide, zirconium oxide, yttrium oxide, scandium oxide, magnesium oxide, chromium dioxide, and vanadium oxide. In some embodiments, oxides used for resistive switching layer 304 generally have some oxygen vacancies to achieve resistive switching, however concentrations of these vacancies are generally smaller than in conventional resistive switching layers. In some embodiments, a concentration of oxygen vacancies in a metal oxide formed into resistive switching layer 304 is less than about 5 atomic percent or, more specifically, less than about 3 atomic percent, e.g., between 0.001 atomic percent and 5 atomic percent. In some embodiments, resistive switching layer 304 includes nitrogen. Nitrogen may be a substitute of oxygen in the above-listed oxides or nitrides may be used without oxygen present. For example, in Ta₂O_{5-X}N_{Y} the value of Y is kept between about 0.001 atomic percent and 5 atomic percent such that the majority of the material is still oxide. The nitrogen is used to control the amount and diffusion of oxygen vacancies within the layer. The same applies to other kinds of nitrogen containing oxides that are used for resistive switching applications. In some embodiments, resistive switching material 304 may have a composition that may be represented by the following formula: Ta₂O_{5-X}N_{Y} in which Y<(X−0.01).

The thickness of resistive switching layer 304 is less than about 50 Angstroms and, in some embodiments, may be less than 30 Angstroms. Resistive switching layer 304 is generally at least 10 Angstroms thick to avoid being too transmissive via tunneling and allowing too much leakage. Tunneling and leaking makes switching difficult and generally reduces distinctiveness of LRS and HRS. The thickness may be precisely controlled using ALD techniques by controlling a number of ALD cycles. For example, a layer formed during each atomic layer deposition cycle may be between about 0.25 and 2 Angstroms thick. The cycle may be repeated multiple times to build up the thickness of the resistive switching layer to the desired level. In some embodiments, atomic layer deposition cycles are repeated using different precursors to create graded composition or introduce and control concentration of oxygen vacancies in the resistive switching layer.

Various performance considerations for specifying thicknesses of resistive switching layers will now be described with reference to FIGS. 3B-3D. Specifically, FIG. 3B illustrates a plot 300 of a median set voltage (the vertical axis—Vset_{—}50P) as a function of the thickness (the right horizontal axis—RS_Thick) and oxygen concentration (the left horizontal axis—RS_O2) in resistive switching layers containing tantalum oxide. This test involves cycling 12 ReRAM cells (i.e., 12 bits) 300 times each, for a total of 3600 cycles. The median of each bit was evaluated and then the median of the 12 bits together is plotted (as X_{—}50P, where X=Vset, Iset, etc.) for each experimental condition. As stated above, the set voltage generally needs as small as possible, for example, less than 2 Volts. As such, the optimal characteristics of resistive switching layers are represented by points located in the top portions of plot 300, i.e., closer to the zero plane. Two sets of such optimal characteristics are identified with circles in FIG. 3B. The left circle 314 corresponds to a resistive switching containing a low oxygen concentration oxide (i.e., metal rich oxide) that is 25 nanometers thick. The right circle 312 corresponds to another resistive switching layer that is formed from a high oxygen concentration oxide (i.e., oxygen rich oxide) that is 5 nanometers thick. While both layers demonstrate substantially the same performance in terms of the set voltage, the thinner layer will be easier to integrate into ICs and 3D memory architectures as explained above.

FIG. 3C illustrates a plot 320 of median values for a set transient (the vertical axis—TRNS_SHLDR_Itest_{—}50P) as a function of the thickness (the right horizontal axis—RS_Thick) and oxygen concentration (the left horizontal axis—RS_O2) in resistive switching layers containing tantalum oxide. As stated above, the set transient is a current overshoot through by the switching layer during a set operation. The set transient may need to be less than 50 micro Amperes in some embodiments (corresponding to 0.00005 on the vertical axis). As with FIG. 3B, the optimal characteristics of resistive switching layers are represented by points located in the top portions of the plot, i.e., closer to the zero plane. Two sets of such optimal characteristics are identified with circles in FIG. 3C. The left circle 324 corresponds to a resistive switching containing a low oxygen concentration oxide (i.e., metal rich oxide) that is 18 nanometers thick. The right circle 322 corresponding to another resistive switching layer that is formed from a high oxygen concentration oxide (i.e., oxygen rich oxide) that is 5 nanometers thick. Again, while both layers demonstrate substantially the same performance in terms of the set voltage, the thinner layer will be easier to integrate into ICs and 3D memory architectures as explained above.

FIG. 3D illustrates a plot of a forming voltage (the vertical axis—V_forming) as a function of the thickness (the right horizontal axis—RS_thick) and oxygen concentration (the left horizontal axis—RS_O2) in resistive switching layers containing tantalum oxide. A forming voltage is applied initially to a newly fabricated ReRAM cell to shift it into its first low resistive state. Generally, forming voltages are higher than set voltages, but it is desirable to keep both types of voltages as low as possible to minimize power consumption and degradation of the ReRAM cell. As such, the optimal characteristics of resistive switching layers are represented by points located in the bottom portions of the plot, i.e., closer to the zero plane. Two sets of such optimal characteristics are identified with circles 334 and 332 in FIG. 3D. Here, the strongest determinant is the thickness, since both circles correspond to the layers that are 5 nanometers thick. Oxygen concentration does not have substantial impact on the forming voltages.

### Processing Examples

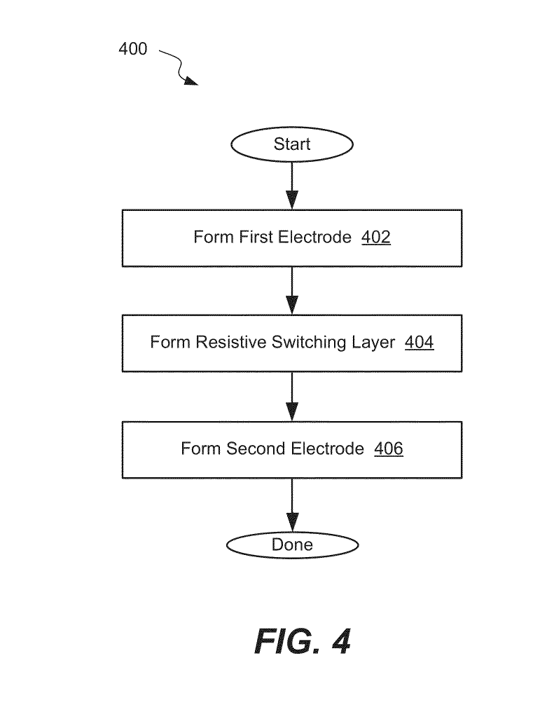

FIG. 4 illustrates a process flowchart corresponding to a method 400 for forming a ReRAM cell, in accordance with some embodiments. The ReRAM cell may include a first layer operable as an electrode, a second layer operable as a resistive switching layer, and a third layer operable as another electrode as described above. Although illustrative processing techniques and process parameters are described, it is understood that various other techniques and modifications of the techniques may also be used. Method 400 may commence with operation 402, during which the first layer is formed. The first layer may include an electrode material, which in some embodiments may be titanium nitride. The titanium nitride electrode may be formed using PVD or another process described above. Specifically, a titanium target may be sputtered at 150-500W with a pressure of 2-10 mTorr in a nitrogen environment. The duration of the sputtering can determine the thickness of the electrode. Other processing techniques, such as ALD, PLD, CVD, evaporation, etc. can also be used to deposit the first layer.

Method 400 may proceed with forming the second layer, i.e., the resistive switching layer in this example, during operation 404. The second layer may be formed using ALD as stated above. This operation may involve one or more ALD cycles, each involving the following four steps: introducing one or more precursors into the depositing chamber to form an absorbed layer, followed by purging these precursors reactive agents, and then introducing reactive agents that will react with the absorbed layer to form a portion of or the entire formed layer, followed by purging the reactive agents reactive agents. Selection of precursors and processing conditions depends on desired composition, morphology, and structure of each portion of the formed layer.

A brief description of an atomic layer deposition technique is presented below to provide better understanding of various processing features. In atomic layer deposition, precursors are introduced into the deposition chamber and allowed to flow over the substrate surface provided therein. The precursors are introduced in the form of pulses. Between the pulses, the reaction chamber is purged, for example, with an inert gas to remove unreacted precursors, reaction products, and other undesirable components from the chamber.

When a precursor is provided above the substrate surface, the precursor may adsorb (e.g., saturatively chemisorb) at that surface. Subsequent pulsing with a purging gas removes excess precursor from the deposition chamber. In some embodiments, purging is performed before full saturation of the substrate surface occurs with the precursors and/or oxidizing agents. In other words, additional precursor and/or oxidizing agent molecules could have been further adsorbed or reacted with the adsorbed molecules on the substrate surface if the purging was not initiated so early. Without being restricted to any particular theory, it is believed that partial saturation can be used to introduced defects into the formed layer, e.g., during forming of a resistive switching layer. As notes, this partial saturation features may be used for metal containing precursors and/or oxidizing agents.

Specifically, adsorption of the metal containing precursor depends on the availability of adsorption sites. When these sites are all consumed (i.e., a fully saturated processing layer is formed), no more metal containing precursor can adsorb, and any remaining precursor is removed by flowing the purge gas. In some embodiments, the metal containing precursor or other precursor used to form a resistive switching layer is not allowed to fully saturate prior to purging and introducing a reactive agent. This partial saturation feature is used to introduce defects into the resistive switching layer. The defects may be needed to provide resistive switching characteristics to the layer.

After the initial precursor pulsing and purging, a subsequent pulse introduces a reactant into the chamber and it reacts with the first precursor adsorbed to the surface (which is sometimes referred to as an intermediate processing layer) and forms the remaining portions of the resistive switching layer. Reaction byproducts and excess reactants are purged from the deposition chamber. In atomic layer deposition, the saturation during the reaction and purging stages makes the growth self-limiting. This feature helps to improve deposition uniformity and conformality and allows more precise control of the resulting resistive switching characteristics.

The precursors used in an atomic layer deposition process may be gaseous, liquid, or solid. However, liquid or solid precursors should be sufficiently volatile to allow introduction as a gas. The vapor pressure should be high enough for effective mass transportation. Also, solid and some liquid precursors may need to be heated and introduced through heated tubes to the substrates. The necessary vapor pressure should be reached at a temperature below the substrate temperature to avoid the condensation of the precursors on the substrate. Due to the self-limiting growth mechanisms of atomic layer deposition, relatively low vapor pressure solid precursors can be used, though evaporation rates may somewhat vary during the process because of changes in their surface area.

Additional characteristics of atomic layer deposition precursors involve thermal stability and adsorption. The precursors should be thermally stable at the substrate temperature because their decomposition would alter the surface control. A slight decomposition, if slow compared to the atomic layer deposition growth, can be tolerated. The precursors should adsorb (e.g., chemisorb) on or react with the surface, though the interaction between the precursor and the surface as well as the mechanism for the adsorption is different for different precursors. The molecules at the substrate surface should react aggressively with the reactant to form the desired layer.

Atomic layer deposition provides continuity at an interface avoiding poorly defined nucleating regions that are typical for chemical vapor deposition and physical vapor deposition. Atomic layer deposition also provides conformality over a variety of substrate topologies due to its layer-by-layer deposition technique, use of low temperature, mildly oxidizing processes, and lack of dependence on the reaction chamber geometry. As described above, the growth thickness in atomic layer deposition depends mainly on the number of cycles performed and ability to form multilayer laminate layers with resolution of one to two mono-layers.

The temperature of the substrate during ALD may be between about 200° C. to 350° C. The precursor may be either in gaseous phase, liquid phase, or solid phase. If a liquid or solid precursor is used, then it may be transported into the chamber an inert carrier gas, such as helium.

In some embodiments, a resistive switching layer containing titanium oxide is deposited using ALD. This operation may start with exposing the substrate surface to a titanium containing precursor, some examples of which include titanium chloride, titanium iodine, bis(tert-butylcyclopentadienyl)titanium dichloride, bis(diethylamido)bis(dimethylamido)titanium, tetrakis(diethylamido)titanium, tetrakis(dimethylamido)titanium, tetrakis(ethylmethylamido)titanium, titanium diisopropoxidebis(2,2,6,6-tetramethyl-3,5-heptanedionate), and titanium isopropoxide. Other titanium containing precursors can be used as well. In some embodiments, a resistive switching layer may include tantalum oxide. Some example of tantalum containing precursors include pentakis (dimethylamino) tantalum, tris(diethylamido) (tert-butylimido) tantalum, tris(diethylamido) (ethylimido) tantalum, tris(ethylmethylamido) (tert-butylimido) tantalum. Other metals suitable for resistive switching layers include niobium oxide, nickel oxide, aluminum oxide, and hafnium oxide. An example of a niobium containing precursor includes bis(cyclopentadienyl) niobium dichloride. Examples of nickel containing precursors include bis(cyclopentadienyl) nickel, bis(ethylcyclopentadienyl) nickel, bis(triphenylphosphine) nickel dichloride, nickel bis(2,2,6,6-tetramethyl-3,5-heptanedionate). Examples of aluminum containing precursors include aluminum tris(2,2,6,6-tetramethyl-3,5-heptanedionate), triisobutylaluminum, trimethylaluminum, tris(dimethylamido) aluminum. Hafnium containing precursors include bis(tert-butylcyclopentadienyl) dimethyl hafnium, bis(methyl-η5-cyclopentadienyl) methoxymethyl hafnium, bis(trimethylsilyl) amido hafnium chloride, dimethylbis(cyclopentadienyl) hafnium, hafnium isopropoxide isopropanol adduct, tetrakis(diethylamido) hafnium, and tetrakis(ethylmethylamido) hafnium. Some hafnium containing precursors can be represented with a formula (RR′N) 4Hf, where R and R′ are independent hydrogen or alkyl groups and may be the same or different. Other precursors for other types of oxides may be used as well.

Following the metal containing precursor pulse and purge, a pulse of an oxidizing agent may be provided to the deposition chamber. Some examples of suitable oxidizing agents include water, peroxides (organic and inorganic, including hydrogen peroxide), oxygen, ozone, oxides of nitrogen, alcohols (e.g., ROH, where R is a methyl, ethyl, propyl, isopropyl, butyl, secondary butyl, or tertiary butyl group, or other suitable alkyl group), carboxylic acids (RCOOH, where R is any suitable alkyl group as above), and radical oxygen compounds (e.g., O, O₂, O₃, and OH radicals produced by heat, hot-wires, and/or plasma). The oxidizing agent reacts with the hafnium containing precursor remaining on the substrate and forms a hafnium oxide layer. The oxidizing agent is purged from the deposition chamber. This cycle may be repeated until the desired thickness of metal oxide is formed.

To form nitrogen containing resistive switching layer, oxidizing agent containing precursor in the above example may be replaced by or combined with a nitrogen containing reactant, such as ammonia.

Method 400 may proceed with operation 406, during which the third layer is formed. The first layer may be formed in a manner similar to the first layer described above.

### ALD Apparatus Examples

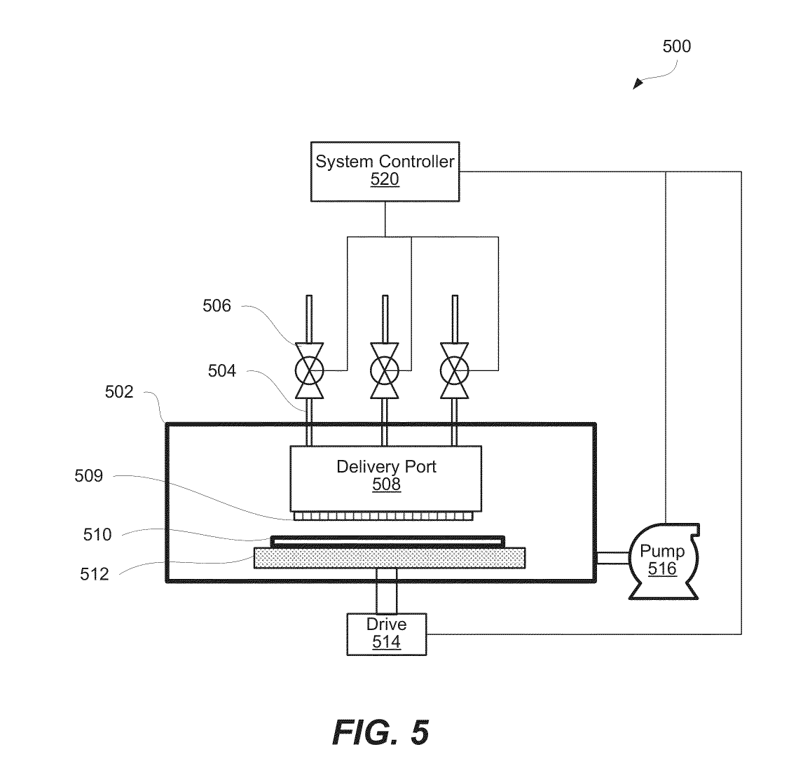

FIG. 5 illustrates a schematic representation of atomic layer deposition apparatus 500 for fabricating nonvolatile memory elements, in accordance with some embodiments. For clarity, some components of apparatus 500 are not included in this figure, such as a wafer-loading port, wafer lift pins, and electrical feed throughs. Apparatus 500 includes deposition chamber 502 connected to processing gas delivery lines 504. While FIG. 5 illustrates three delivery lines 504, any number of delivery lines may be used. Each line may be equipped with a valve and/or mass flow controller 506 for controlling the delivery rates of processing gases into deposition chamber 502. In some embodiments, gases are provided into delivery port 508 prior to exposing substrate 510 to processing gases. Deliver port 508 may be used for premixing gases (e.g., precursors and diluents) and even distribution of gases over the surface of substrate 510. Delivery port 508 is sometimes referred to as a showerhead. Delivery port 508 may include a diffusion plate 509 having with multiple holes for gas distribution.

Deposition chamber 502 encloses substrate support 512 for holding substrate 510 during its processing. Substrate support 512 may be made from a thermally conducting metal (e.g., W, Mo, Al, Ni), ceramic, or other like materials and may be used to maintain the substrate temperature at desired levels. Substrate support 512 may be connected to drive 514 for moving substrate 510 during loading, unloading, process set up, and sometimes even during processing. Deposition chamber 502 may be connected to vacuum pump 516 for evacuating reaction products and unreacted gases from deposition chamber 502 and for maintaining the desirable pressure inside chamber 502.

Apparatus 500 may include system controller 520 for controlling process conditions during electrode and resistive switching layer deposition and other processes. Controller 520 may include one or more memory devices and one or more processors with a CPU or computer, analog and/or digital input/output connections, stepper motor controller boards, etc. In some embodiments, controller 520 executes system control software including sets of instructions for controlling timing, gas flows, chamber pressure, chamber temperature, substrate temperature, RF power levels (if RF components are used, e.g., for process gas dissociation), and other parameters. Other computer programs and instruction stored on memory devices associated with controller may be employed in some embodiments.

### Memory Array Examples

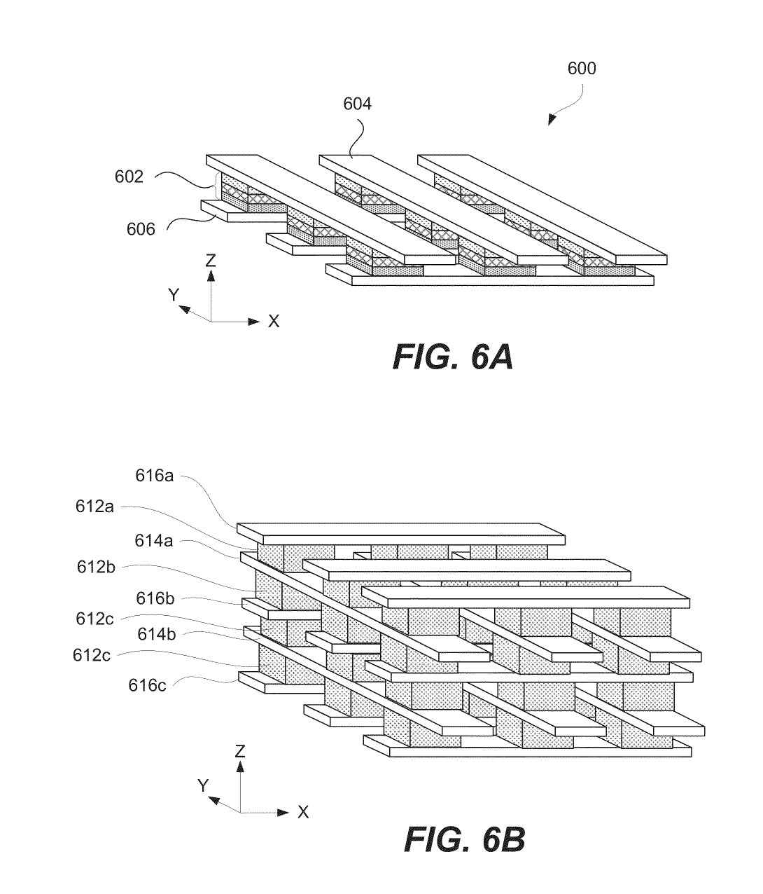

A brief description of memory arrays will now be described with reference to FIGS. 6A and 6B to provide better understanding to various aspects of thermally isolating structures provided adjacent to nonvolatile memory elements and, in some examples, surrounding the nonvolatile memory elements. Nonvolatile memory elements described above may be used in memory devices or larger integrated circuits (IC) that may take a form of arrays. FIG. 6A illustrates a memory array 600 including nine nonvolatile memory elements 602, in accordance with some embodiments. In general, any number of nonvolatile memory elements may be arranged into one array. Connections to each nonvolatile memory element 602 are provided by signal lines 604 and 606, which may be arranged orthogonally to each other. Nonvolatile memory elements 602 are positioned at crossings of signal lines 604 and 606 that typically define boundaries of each nonvolatile memory element in array 600.

Signal lines 604 and 606 are sometimes referred to as word lines and bit lines. These lines are used to read and write data into each nonvolatile memory element 602 of array 600 by individually connecting nonvolatile memory elements to read and write controllers. Individual nonvolatile memory elements 602 or groups of nonvolatile memory elements 602 can be addressed by using appropriate sets of signal lines 604 and 606. Each nonvolatile memory element 602 typically includes multiple layers, such as top and bottom electrodes, resistance switching layer, embedded resistors, embedded current steering elements, and the like, some of which are further described elsewhere in this document. In some embodiments, a nonvolatile memory element includes multiple resistance switching layers provided in between a crossing pair of signal lines 604 and 606.

As stated above, various read and write controllers may be used to control operations of nonvolatile memory elements 602. A suitable controller is connected to nonvolatile memory elements 602 by signal lines 604 and 606 and may be a part of the same memory device and circuitry. In some embodiments, a read and write controller is a separate memory device capable of controlling multiple memory devices each one containing an array of nonvolatile memory elements. Any suitable read and write controller and array layout scheme may be used to construct a memory device from multiple nonvolatile memory elements. In some embodiments, other electrical components may be associated with the overall array 600 or each nonvolatile memory element 602. For example, to avoid the parasitic-path-problem, i.e., signal bypasses by nonvolatile memory elements in their low resistance state (LRS), serial elements with a particular non-linearity must be added at each node or, more specifically, into each element. Depending on the switching scheme of the nonvolatile memory element, these elements can be diodes or varistor-type elements with a specific degree of non-linearity. In the same other embodiments, an array is organized as an active matrix, in which a transistor is positioned at each node or, more specifically, embedded into each cell to decouple the cell if it is not addressed. This approach significantly reduces crosstalk in the matrix of the memory device.

In some embodiments, a memory device may include multiple array layers as, for example, illustrated in FIG. 6B. In this example, five sets of signal lines 614a-b and 616a-c are shared by four ReRAM arrays 612a-c. As with the previous example, each ReRAM array is supported by two sets of signal lines, e.g., array 612a is supported by 614a and 616a. However, middle signal lines 614a-b and 616b, each is shared by two sets ReRAM arrays. For example, signal line set 614a provides connections to arrays 612a and 612b. Top and bottom sets of signal lines 616a and 616c are only used for making electrical connections to one array. This 3-D arrangement of the memory device should be distinguished from various 3-D arrangements in each individual nonvolatile memory element.

### CONCLUSION

Although the foregoing examples have been described in some detail for purposes of clarity of understanding, the invention is not limited to the details provided. There are many alternative ways of implementing the invention. The disclosed examples are illustrative and not restrictive.

1. A resistive random access memory cell comprising:
a first layer operable as a first electrode;
a second layer comprising a resistive switching material,
the resistive switching material comprises oxygen vacancies,
a concentration of oxygen vacancies in the resistive switching material being less than 5 atomic percent,
the second layer having a thickness of less than 50 Angstroms; and
a third layer operable as a second electrode,
wherein the second layer is positioned between the first layer and the third layer.

2. The resistive random access memory cell of claim 1, wherein the resistive switching material further comprises nitrogen.

3. The resistive random access memory cell of claim 1, wherein the resistive switching material comprises tantalum oxide.

4. The resistive random access memory cell of claim 1, wherein the resistive switching material comprises tantalum and nitrogen.

5. The resistive random access memory cell of claim 1, wherein the resistive switching material is represented by a formula Ta₂O_{5-X}N_{Y} such that Y<(X−0.01).

6. The resistive random access memory cell of claim 1, wherein the second layer has a thickness of less than 30 Angstroms.

7. The resistive random access memory cell of claim 1, wherein the concentration of oxygen vacancies in the resistive switching material is less than 3 atomic percent.

8. The resistive random access memory cell of claim 1, wherein the third layer comprises titanium nitride.

9. The resistive random access memory cell of claim 8, wherein the third layer has a thickness of less than 1,000 Angstroms.

10. The resistive random access memory cell of claim 1, wherein the first layer comprises n-doped polysilicon.

11. A method of forming a resistive random access memory cell, the method comprising:
forming a first layer operable as a first electrode;
forming a second layer over the first layer,
the second layer comprising a resistive switching material,
the resistive switching material comprising a metal oxide having,
the concentration of oxygen vacancies in the metal oxide being less than 5 atomic percent,
the second layer having a thickness of less than 50 Angstroms; and
forming a third layer over the second layer, the third layer operable as a second electrode.

12. The method of claim 11, wherein the second layer is formed using Atomic Layer Deposition (ALD).

13. The method of claim 12, wherein the concentration of oxygen vacancies is achieved by controlling saturation of an oxygen containing reagent during ALD.

14. The method of claim 12, wherein the second layer comprises tantalum.

15. The method of claim 14, where a precursor used for depositing the second layer is one of pentakis (dimethylamino) tantalum, tris(diethylamido) (tert-butylimido) tantalum, tris(diethylamido) (ethylimido) tantalum, or tris(ethylmethylamido) (tert-butylimido) tantalum.

16. The method of claim 12, wherein a nitrogen containing reagent is used during the ALD forming.

17. The method of claim 11, wherein the first layer is formed using Chemical Vapor Deposition (CVD) and wherein the first layer comprises n-doped polysilicon.

18. The method of claim 11, wherein the third layer is formed using Physical Vapor Deposition (PVD) and wherein the third layer comprises titanium nitride.

19. The method of claim 18, wherein the first layer is formed using Chemical Vapor Deposition (CVD) and comprises n-doped polysilicon, wherein the second layer is formed using Atomic Layer Deposition (ALD) and wherein the resistive switching material is represented by a formula Ta₂O_{5-X}N_{Y} such that Y<(X−0.01).

20. A resistive random access memory cell comprising:
a first layer operable as a first electrode,
the first layer comprising n-doped polysilicon;
a second layer comprising a resistive switching material,
the resistive switching material is represented by a formula Ta₂O_{5-X}N_{Y} such that Y<(X−0.01),
the resistive switching material comprises oxygen vacancies,
a concentration of oxygen vacancies in the resistive switching material being less than 5 atomic percent,
the second layer having a thickness of less than 50 Angstroms; and
a third layer operable as a second electrode,
the third layer comprising a titanium nitride having a thickness of less than 1,000 Angstroms,
wherein the second layer is positioned between the first layer and the third layer.
